(19) United States
(12) Patent Application Publication
(10) Pub. No.: US 2020/0275755 A1
(43) Pub. Date: Sep. 3, 2020

(54) RADIATIONLESS HAIR DRYER

(71) Applicant: Annie Hsu, Hangzhou City, Zhejiang Province (CN)

(72) Inventor: Annie Hsu, Hangzhou City, Zhejiang Province (CN)

(21) Appl. No.: 16/288,997

(22) Filed: Feb. 28, 2019

(51) Int. Cl. A45D 20/12; H05K 9/00

(52) U.S. Cl. CPC A45D 20/12; H05K 9/0075; H05K 9/0081

(57) ABSTRACT

The present disclosure relates to a radiationless hair dryer, and belongs to the field of hair dryers. In the radiationless hair dryer, a magnetic field shielding enclosed space without leakage is formed by a shielding housing and a metal air outlet net at an air outlet of the shielding housing; the shielding housing and a brushless motor are connected with an earth wire so as to leak electromagnetic radiation; a first electrically heated wire and a second electrically heated wire are respectively and mutually alternatively wound around a mica frame in the same direction, and the direction of current flowing the first electrically heated wire and the direction of current flowing the second electrically heated wire are opposite, so that an electromagnetic field generated by the first electrically heated wire and an electromagnetic field generated by the second electrically heated wire are counteracted with each other.

### BACKGROUND OF THE INVENTION

### Field of the Invention

The present disclosure belongs to the field of hair dryers, and specifically relates to a radiationless hair dryer.

### Description of the Related Art

The hair dryer consists of a group of electrically heated wires and a blade which are arranged in a housing. When the hair dryer is powered on, the electrically heated wires generate heat, the blade rotates to blow the heat out, and at this time, the hair dryer blows hot wind out; when people do not need the hot wind, they only need to press a switching button on the housing, and at this time, the electrically heated wires do not generate the heat and the blade rotates to blow cold wind out; and when an air outlet of the hair dryer is putted to the hair to blow, the hair may be dried.

In the prior art, a conventional hair dryer generates heat by heating electrically heated wires, wherein the electrically heated wires are made from Fe—Cr—Al alloy or Ni—Cr electrical thermal alloy with relatively higher melting point and relatively stronger oxidation resistance; the electrically heated wires are arranged in the hair dryer in a winding manner, and due to different winding manners, the electrically heated wires may generate a large amount of electromagnetic radiation while being heated; and the electrically heated wires are heated by thermal radiation.

When people use a hair dryer to dry the hair, magnetic field radiation and electric field radiation generated by a power cord per se, electrically heated wires and a brushless motor will spread around, so that surrounding people, especially a person whose hair is to be dried, are placed under the electromagnetic pollution environment; electromagnetic radiation generated by the electrically heated wires will directly act on the head of the person to cause some radiation damage to its body; additionally, after the electrically heated wires are heated, the temperature of the electrically heated wires will continuously increase, the wind blown out by the electrically heated wires will be hotter and hotter, and meanwhile, the quantity of the wind is uneven, so, if people use the hair dryer to dry the hair, there will generate dangers of scorching local hair or scalp. Because people usually need to care the hair, the use frequency of the hair dryer is high, and if people use such hair dryer for a long term, their head will suffer a large amount of electromagnetic radiation so as to affect the health of people.

At present, there have been associated patents which provide schemes to solve electric field radiation and magnetic field radiation generated when the hair dryer is working, for example, a scheme of solving the electric field radiation generated by the power cord, and a scheme of solving the electric field radiation and the magnetic radiation generated by each function components (such as electrically heated wires and a brushless motor) in the hair dryer. However, all of these schemes only solve the radiation locally and have deficiencies in the aspect of eliminating radiation of the hair dryer, and hair dryers utilizing the schemes of the prior art still generate a large amount of radiation in use. Moreover, all of these schemes of the prior art are provided to reduce or eliminate the generated radiation, and there are no new schemes to avoid radiation generation.

### SUMMARY OF THE INVENTION

Accordingly, an objective of the present disclosure is to provide a radiationless hair dryer, which reduces and further eliminates radiation generated by a hair dryer, so as to overcome the deficiencies of the prior art.

In order to achieve the objective, the present disclosure adopts the following technical scheme.

A radiationless hair dryer comprises a shielding housing, a mica frame, a brushless motor, an AC/DC switching module, a blade, honeycomb ceramic, a first electrically heated wire, a second electrically heated wire, a metal air outlet net and a power cord;
the mica frame is disposed in the shielding housing, the honeycomb ceramic is clamped at the front end of the mica frame, the brushless motor is arranged at the back end of the mica frame, the blade is arranged on a motor shaft of the brushless motor, the brushless motor is connected with the AC/DC switching module, and the AC/DC switching module is connected with the power cord;
the metal air outlet net is arranged at an air outlet of the shielding housing and is electrically connected with the shielding housing, and the shielding housing is electrically connected with a housing of the brushless motor;
the power cord comprises a live wire, a neutral wire, an earth wire and a power cord shielding layer, wherein the power cord shielding layer covers the neutral wire, the live wire and the earth wire, and the neutral wire, the live wire and the earth wire are in form of a stranded wire; the shielding housing is respectively connected with the earth wire and the power cord shielding layer; and
the first electrically heated wire and the second electrically heated wire are respectively and mutually alternatively wound around the mica frame in the same direction; the first electrically heated wire and the second electrically heated wire are in parallel connection with the live wire and the neutral wire, and the direction of current flowing the first electrically heated wire and the direction of current flowing the second electrically heated wire are opposite.

Furthermore, the honeycomb ceramic is tourmaline honeycomb ceramic.

Furthermore, the honeycomb ceramic is a positive temperature coefficient (PTC) honeycomb ceramic or thin-film honeycomb ceramic heater, and the PTC honeycomb ceramic or thin-film honeycomb ceramic heater is respectively connected with the power cord.

Furthermore, the radiationless hair dryer further comprises a radiation elimination component, wherein the radiation elimination component is made from a graphene material, a nanometer lanthanide-series rare earth oxide material or a ferromagnetic material; and the live wire, the neutral wire, the earth wire and the power cord shielding layer of the power cord, and the shielding housing are respectively connected with the radiation elimination component.

Furthermore, recesses are formed in the outer side of the mica frame, and the first electrically heated wire and the second electrically heated wire are respectively wound around the recesses.

Furthermore, through holes are formed in the mica frame, and the first electrically heated wire and the second electrically heated wire are wound around the mica frame after respectively passing through the through holes.

Furthermore, the power cord shielding layer of the power cord is made from any one of an aluminum foil, a lead foil, a copper foil, woven wire cloth and a nickel-carbon conductive adhesive, or the power cord shielding layer of the power cord is prepared by spraying conductive paste or conductive paint, wherein the woven wire cloth comprises a bare copper mesh or a tin-plated copper mesh, and the conductive paste comprises carbon powder conductive paste.

Furthermore, the shielding housing is made of metal materials, or a housing body of the shielding housing is made of plastic, and a high-temperature-resistance conductive coating is arranged on the inner surface of the housing body.

Furthermore, the high-temperature-resistance conductive coating is arranged on the surface of the honeycomb ceramic or the thick-film ceramic.

Furthermore, the high-temperature-resistance conductive coating is prepared by coating the nickel-carbon conductive adhesive, or spraying any one of the conductive paint and the conductive paste, wherein the conductive paste comprises carbon power conductive paste.

By adopting the above technical scheme, the present disclosure at least has the following beneficial effects:
the present disclosure provides a radiationless hair dryer, wherein a magnetic field shielding enclosed space without leakage is formed by the shielding housing and the metal air outlet net at the air outlet of the shielding housing; the shielding housing and the brushless motor are connected with the earth wire so as to leak the electromagnetic radiation; the first electrically heated wire and the second electrically heated wire are respectively and mutually alternatively wound around the mica frame in the same direction, and the direction of current flowing the first electrically heated wire and the direction of current flowing the second electrically heated wire are opposite, so that an electromagnetic field generated by the first electrically heated wire and an electromagnetic field generated by the second electrically heated wire are counteracted with each other; the power cord shielding layer of the power cord covers the neutral wire, the live wire and the earth wire so as to eliminate electric field radiation generated by the power cord per se, and the neutral wire, the live wire and the earth wire are stranded wires so that electric waves radiated by one wire during transmission may be counteracted by electric waves radiated by another wire; and the brushless motor is configured to reduce the generation of radiation; therefore, by all of the radiation elimination manners, an objective of reducing and further eliminating the radiation generated by the hair dryer is achieved.

### BRIEF DESCRIPTION OF THE DRAWINGS

FIG. 1 is a schematic diagram of a radiationless hair dryer provided by the present disclosure.

FIG. 2 is a winding schematic diagram of a first electrically heated wire and a second electrically heated wire of the radiationless hair dryer provided by the present disclosure.

FIG. 3 is a schematic diagram of honeycomb ceramic of the radiationless hair dryer provided by the present disclosure.

FIG. 4 is a schematic diagram of recesses formed in a mica frame of the radiationless hair dryer provided by the present disclosure.

FIG. 5 is a schematic diagram of through holes formed in the mica frame of the radiationless hair dryer provided by the present disclosure.

In accompanying drawings: 1-shielding housing; 2-mica frame; 3-brushless motor; 4-blade; 5-honeycomb ceramic; 6-first electrically heated wire; 7-second electrically heated wire; 8-metal air outlet net; 9-power cord; 201-recess; and 202-through hole.

### DETAILED DESCRIPTION OF THE SEVERAL EMBODIMENTS

The technical scheme of the present disclosure is further described below in detail in conjunction with accompanying drawings and embodiments.

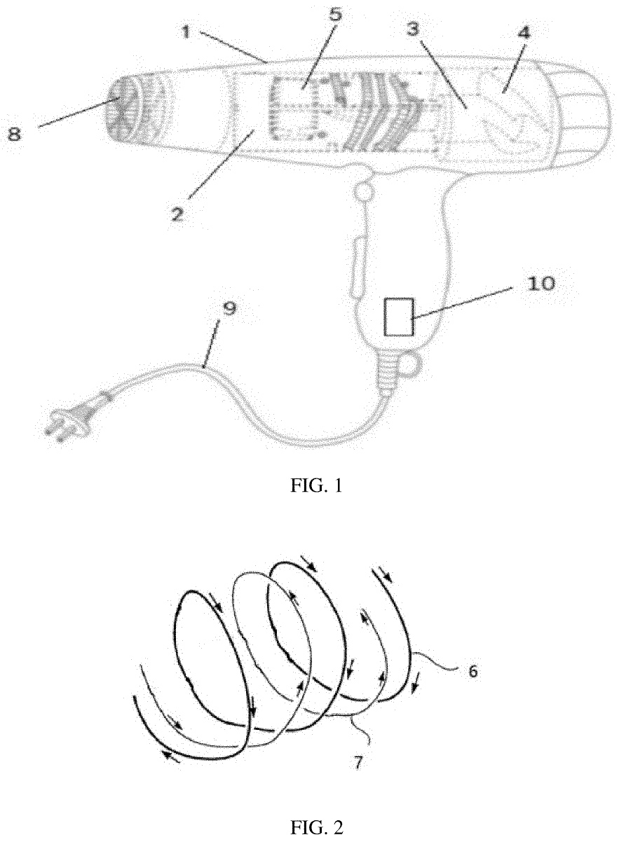

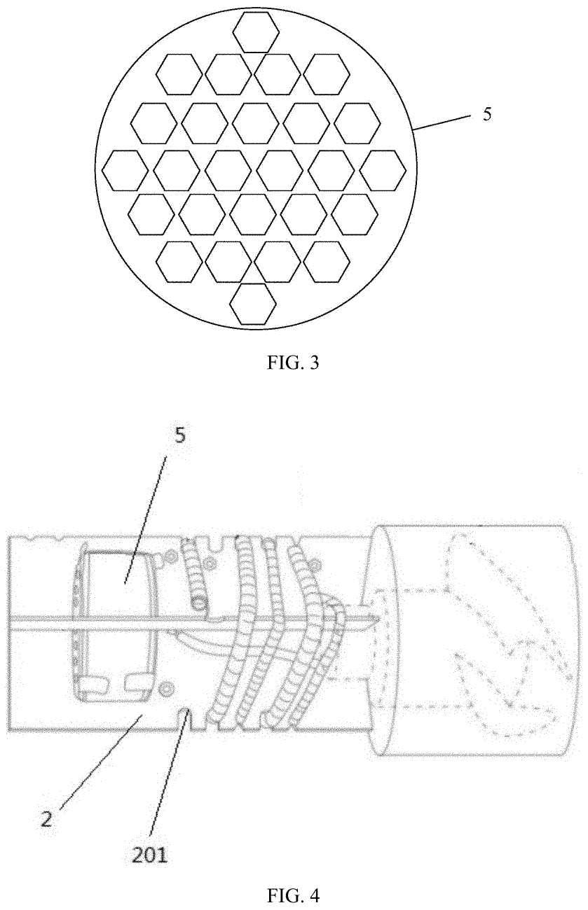

As shown in FIG. 1, FIG. 2 and FIG. 3, the present disclosure provides a radiationless hair dryer, which comprises a shielding housing 1, a mica frame 2, a brushless motor 3, a blade 4, honeycomb ceramic 5, a first electrically heated wire 6, a second electrically heated wire 7, a metal air outlet net 8, a power cord 9 and an AC/DC switching module 10;
the mica frame 2 is disposed in the shielding housing 1, the honeycomb ceramic 5 is clamped at the front end of the mica frame 2, the brushless motor 3 is arranged at the back end of the mica frame 2, the blade 4 is arranged on a motor shaft of the brushless motor 3, the brushless motor 3 is connected with the AC/DC switching module 10, and the AC/DC switching module 10 is connected with the power cord 9;
the metal air outlet net 8 is arranged at an air outlet of the shielding housing 1 and is electrically connected with the shielding housing 1, and the shielding housing 1 is electrically connected with a housing of the brushless motor 3;
the power cord 9 comprises a live wire, a neutral wire, an earth wire and a power cord shielding layer, wherein the power cord shielding layer covers the neutral wire, the live wire and the earth wire, and the neutral wire, the live wire and the earth wire are in form of a stranded wire; the shielding housing 1 is respectively connected with the earth wire and the power cord shielding layer; and
the first electrically heated wire 6 and the second electrically heated wire 7 are respectively and mutually alternatively wound around the mica frame 2 in the same direction; the first electrically heated wire 6 and the second electrically heated wire 7 are in parallel connection with the live wire and the neutral wire, and the direction of current flowing the first electrically heated wire 6 and the direction of current flowing the second electrically heated wire 7 are opposite.

Understandably, in the radiationless hair dryer provided by the present disclosure, a magnetic field shielding enclosed space without leakage is formed by the shielding housing 1 and the metal air outlet net 8 at the air outlet of the shielding housing 1, meanwhile, the shielding housing 1, the metal air outlet net 8 and the brushless motor 3 are electrically connected, and then the shielding housing 1 is connected with the earth wire to leak the magnetic field radiation, thereby achieving elimination of electromagnetic radiation and electric field radiation; and the brushless motor 3 is a DC motor which may largely reduce the radiation in comparison with an AC motor.

As shown in FIG. 2, the first electrically heated wire and the second electrically heated wire are respectively and mutually alternatively wound around the mica frame in the same direction, and the direction of current flowing the first electrically heated wire and the direction of current flowing the second electrically heated wire are opposite, so that an electromagnetic field generated by the first electrically heated wire and an electromagnetic field generated by the second electrically heated wire are counteracted with each other, and at this time, the electromagnetic radiation generated by the electrically heated wires is eliminated; and the power cord shielding layer of the power cord covers the neutral wire, the live wire and the earth wire, and the neutral wire, the live wire and the earth wire are stranded wires so that electric waves radiated by one wire during transmission may be counteracted by electric waves radiated by another wire, thereby eliminating the electric field radiation generated by the power cord per se.

The power cord shielding layer of the power cord 9 is made from any one of an aluminum foil, a lead foil, a copper foil, woven wire cloth and a nickel-carbon conductive adhesive, or the power cord shielding layer is prepared by spraying conductive paste or conductive paint, wherein the woven wire cloth comprises a bare copper mesh or a tin-plated copper mesh, and the conductive paste comprises carbon powder conductive paste. The electric field radiation generated by the neutral wire, the live wire and the earth wire may be further shielded by the power cord shielding layer, and during actual use, the conductive resistance of the conductive paste or the conductive paint is preferably smaller than 15 ohms.

To sum up, the present disclosure utilizes the above plurality of manners to reduce, eliminate and shield the electromagnetic radiation and the electric field radiation. By comparing the prior art with the present disclosure, the prior art merely uses a single manner to eliminate the electromagnetic radiation and the electric field radiation, and the electromagnetic radiation still exists and is massive; but the present disclosure considers two aspects of radiation generation and radiation elimination and uses the plurality of manners to cooperate to eliminate the radiation to the greatest extent, thereby achieving an objective that no damage is generated to the human body.

As shown in FIG. 3, in the present disclosure, through holes of the honeycomb ceramic 5 face to the air outlet of the shielding housing 1 during actual use. The honeycomb ceramic 5 preferably utilizes tourmaline honeycomb ceramic in the present disclosure, wherein tourmaline has a plurality of functions and applications, for example, it may generate negative ions and far infrared rays, and may shield the electromagnetic radiation, so, if the tourmaline is applied to the hair dryer of the present disclosure, its function of shielding the electromagnetic radiation may be achieved, and negative ions may also be excited to generate in the air. When the tourmaline contacts with the air, the electric field of the tourmaline acts on water molecules (whose decomposition voltage is 1.23 V) in the air to ionize it into OH—, the OH— attracts water molecules in the air to form OH—(H2O)n so as to increase the concentration of the negative ions in the air, the generated negative ions may effectively improve the neurasthenia, the insomnia and the like of people, may clear the heart and cerebral vessels, and may reduce the blood viscosity so as to improve the immunity of the human body, and the generated negative ions have remarkable curative effects of improving the insomnia and the asthma and releasing the hypertension, the diabetes and the like. Additionally, the generated far infrared ray has the similar vibration frequency with cell molecules in the human body, so, when the far infrared ray irradiates the human body, it will cause resonance between atoms and molecules of human body cells, and depending on resonance absorption, the molecules generate the heat by friction to generate a thermal reaction, thereby facilitating increase of the subcutaneous deeper tissue temperature and dilation of the capillaries, accelerating the blood circulation, helping vascular accumulations and in-vivo harmful substances to be cleaned, clearing away obstacles which influence the metabolism, repeatedly recovering the tissues, facilitating the generation of ferments and achieving objectives of activating tissue cells, preventing aging and intensifying the immune system; therefore, the far infrared ray has functions of improving, preventing and curing various diseases caused by blood circulation disturbances and microcirculation disturbances; furthermore, a plurality of harmful substances in the human body, such as heavy metal and other toxic substances in foods lactic acid, free fatty acid, fat, subcutaneous fat, sodium ions, uric acid, cosmetic residues accumulated in capillary pores and the like, may be directly discharged from the skin with the sweats in a metabolism manner without passing through the kidney, so the increase of the kidney burden may be avoided.

As another preferable scheme, the honeycomb ceramic provided by the present disclosure may also be the positive temperature coefficient (PTC) honeycomb ceramic. The PTC honeycomb ceramic is connected with the power cord in order to further achieve the heating function. PTC thermistor ceramic is a type of semiconductor functional ceramic with positive temperature coefficient. When the temperature of the PTC is smaller than the transformation temperature, the resistance is reduced along with the increase of the temperature, and when the temperature is greater than the transformation temperature and is smaller than the thermal runaway temperature, the resistance is remarkably increased along with the increase of the temperature, which is the PTC effect. During actual use, the PTC effect may be utilized, current passes through a resistance-type ceramic heating element to generate heat so as to achieve the heating function, such heating principle does not generate electromagnetic radiation, and a PTC element further has the advantages of high reliability, convenience in use, safety, power saving and the like. Because a honeycomb PTC has a simple structure, it may keep power stable without adding a temperature control device and using the conductive adhesive or other heat dissipation devices in use, and a honeycomb porous PTC does not turn red, is safe and reliable, and has long service life when being heated, so it has a wide use voltage range.

Furthermore, the honeycomb ceramic 1 provided by the present disclosure may also utilize a thick-film honeycomb ceramic to further achieve the heating function. The thick-film heating technique is a novel heating technique utilizing a thick-film heater (such as a thick-film heating plate), and its heating principle does not generate the electromagnetic radiation, so this technique is widely applied now. The thick-film heating plate is a novel heating device prepared by printing an insulating medium, a heating resistor, a conductor, glass protective glaze and the like on a stainless steel or ceramic substrate by utilizing a thick-film silk-screen printing technique and carrying out high-temperature sintering.

In order to further eliminate the electromagnetic radiation, the present disclosure further provides a preferable scheme, wherein the radiationless hair dryer further comprises a radiation elimination component, the radiation elimination component is made from a graphene material, a nanometer lanthanide-series rare earth oxide material or a ferromagnetic material, and its shape may be designed to be a cavity structure capable of accommodating the mica frame and the motor; and the live wire, the neutral wire, the earth wire and the power cord shielding layer of the power cord, and the shielding housing are respectively connected with the radiation elimination component.

Wherein graphene as a currently popular novel material has outstanding conductivity, an excellent electromagnetic shielding function and an excellent wave absorbing function; and the particle sizes of the nanometer lanthanide-series rare earth oxide material and the ferromagnetic material are generally smaller than wavelengths for exciting or emitting light waves, so various electromagnetic waves may be approximated to be uniform in a particle range, and there does not exist a micro-cavity effect caused by a broadcasting range limitation function. Furthermore, the size of the nanometer rare earth material is very small, but its specific surface area is very large, thereby generating a large surface state density. Based on combination of the two aspects, the nanometer rare earth material shows unique electromagnetic wave absorption property. If nanometer rare earth oxide particles are taken as the electromagnetic wave absorption material, lead-free, nontoxic and light electromagnetic protection material may be obtained. The graphene material, the nanometer lanthanide-series rare earth oxide material or the ferromagnetic material are used for manufacturing the radiation elimination component, thereby achieving the function of absorbing the electromagnetic wave.

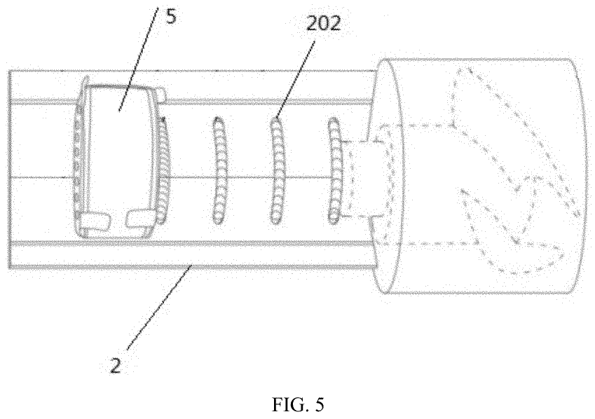

As shown in FIG. 4 and FIG. 5, the present disclosure provides the following two preferable schemes in order to greatly fix the first electrically heated wire 6 and the second electrically heated wire 7 to the mica frame 2 and prevent the electrically heated wires from falling off and shaking, wherein a first scheme is: recesses 201 are formed in the outer side of the mica frame 2, and the first electrically heated wire 6 and the second electrically heated wire 7 are respectively wound around the recesses 201; and a second scheme is: through holes 202 are formed in the mica frame 2, and the first electrically heated wire 6 and the second electrically heated wire 7 are wound around the mica frame 2 after respectively passing through the through holes 202.

In the present disclosure, the shielding housing 1 may be made of metal materials; preferably a housing body of the shielding housing is made of plastic, and a high-temperature-resistance conductive coating is arranged on the inner surface of the housing body. The high-temperature-resistance conductive coating is prepared by coating the nickel-carbon conductive adhesive, or spraying any one of the conductive paint and the conductive paste, wherein the conductive paste comprises carbon power conductive paste. Additionally, the high-temperature-resistance conductive coating may also be arranged on the surface of the honeycomb ceramic or the surface of the thick-film ceramic.

The above specific embodiments further describe the objective, the technical scheme and the beneficial effects of the present disclosure in details. It should be understood that: the above are preferred embodiments of the present disclosure merely, and are not intended to limit the present disclosure. Any modifications, equivalent substitutes and improvements, etc., made within the spirit and principle of the present disclosure all are intended to be included in the protection scope of the present disclosure.

What is claimed is:

1. A radiationless hair dryer, characterized in that: the radiationless hair dryer comprises a shielding housing, a mica frame, a brushless motor, an AC/DC switching module, a blade, honeycomb ceramic, a first electrically heated wire, a second electrically heated wire, a metal air outlet net and a power cord;
the mica frame is disposed in the shielding housing, the honeycomb ceramic is clamped at the front end of the mica frame, the brushless motor is arranged at the back end of the mica frame, the blade is arranged on a motor shaft of the brushless motor, the brushless motor is connected with the AC/DC switching module, and the AC/DC switching module is connected with the power cord;
the metal air outlet net is arranged at an air outlet of the shielding housing and is electrically connected with the shielding housing, and the shielding housing is electrically connected with a housing of the brushless motor;
the power cord comprises a live wire, a neutral wire, an earth wire and a power cord shielding layer, wherein the power cord shielding layer covers the neutral wire, the live wire and the earth wire, and the neutral wire, the live wire and the earth wire are in form of a stranded wire; the shielding housing is respectively connected with the earth wire and the power cord shielding layer; and
the first electrically heated wire and the second electrically heated wire are respectively and mutually alternatively wound around the mica frame in the same direction; the first electrically heated wire and the second electrically heated wire are in parallel connection with the live wire and the neutral wire, and the direction of current flowing the first electrically heated wire and the direction of current flowing the second electrically heated wire are opposite.

2. The radiationless hair dryer according to claim 1, characterized in that: the honeycomb ceramic is tourmaline honeycomb ceramic.

3. The radiationless hair dryer according to claim 1, characterized in that: the honeycomb ceramic is a positive temperature coefficient (PTC) honeycomb ceramic or thin-film honeycomb ceramic heater, and the PTC honeycomb ceramic or thin-film honeycomb ceramic heater is respectively connected with the power cord.

4. The radiationless hair dryer according to claim 1, characterized in that: the radiationless hair dryer further comprises a radiation elimination component, wherein the radiation elimination component is made from a graphene material, a nanometer lanthanide-series rare earth oxide material or a ferromagnetic material; and the live wire, the neutral wire, the earth wire and the power cord shielding layer of the power cord, and the shielding housing are respectively connected with the radiation elimination component.

5. The radiationless hair dryer according to claim 4, characterized in that: recesses are formed in the outer side of the mica frame, and the first electrically heated wire and the second electrically heated wire are respectively wound around the recesses.

6. The radiationless hair dryer according to claim 4, characterized in that: through holes are formed in the mica frame, and the first electrically heated wire and the second electrically heated wire are wound around the mica frame after respectively passing through the through holes.

7. The radiationless hair dryer according to claim 1, characterized in that: the power cord shielding layer of the power cord is made from any one of an aluminum foil, a lead foil, a copper foil, woven wire cloth and a nickel-carbon conductive adhesive, or the power cord shielding layer of the power cord is prepared by spraying conductive paste or conductive paint, wherein the woven wire cloth comprises a bare copper mesh or a tin-plated copper mesh, and the conductive paste comprises carbon powder conductive paste.

8. The radiationless hair dryer according to claim 1, characterized in that: the shielding housing is made of metal materials, or a housing body of the shielding housing is made of plastic, and a high-temperature-resistance conductive coating is arranged on the inner surface of the housing body.

9. The radiationless hair dryer according to claim 1, characterized in that: the high-temperature-resistance conductive coating is arranged on the surface of the honeycomb ceramic or the surface of the thick-film ceramic.

10. The radiationless hair dryer according to claim 8, characterized in that: the high-temperature-resistance conductive coating is prepared by coating the nickel-carbon conductive adhesive, or spraying any one of the conductive paint and the conductive paste, wherein the conductive paste comprises carbon power conductive paste.
